(19) United States
(12) Patent Application Publication
(10) Pub. No.: US 2011/0317386 A1
(43) Pub. Date: Dec. 29, 2011

(54) CONNECTING STRUCTURE, CIRCUIT DEVICE AND ELECTRONIC APPARATUS

(75) Inventor: Masahito Kawabata, Kanagawa (JP)

(73) Assignee: PANASONIC CORPORATION, Osaka (JP)

(21) Appl. No.: 13/254,685

(22) PCT Filed: Dec. 8, 2009
(86) PCT No.: PCT/JP2009/006697

§ 371 Date: Sep. 2, 2011

(30) Foreign Application Priority Data
Mar. 19, 2009 (JP) 2009-068021

(51) Int. Cl. H01R 12/50; H05K 1/14

(52) U.S. Cl. 361/772; 361/803

(57) ABSTRACT

To provide a connecting structure which can effectively suppress the generation of a crack and an exfoliation of a terminal. The connecting structure includes a frame 31 which includes a first connection surface 31A to be connected to a connector board 20, a second connection surface 31B to be connected to a circuit board 10, and a first side surface 31C and a second side surface 31D each crossing with the first connection surface 31A and the second connection surface 31B; a signal terminal 33 which includes a conductive first terminal portion 33A formed at the first connection surface 31A and a conductive second terminal portion 33B formed at the second connection surface 31B; and a grounding terminal 32 which includes a conductor 32D formed at the second side surface 31D in a state of being separated from the signal terminal 33 via an exposed portion of the insulative frame 31, wherein a concave portion G is formed at each of the first connection surface 31A and the second connection surface 31B, and a first terminal portion 32A or a second terminal portion 32B is formed along the concave portion G, respectively.

### TECHNICAL FIELD

The present invention relates to a connecting structure for electrically and mechanically coupling two members, a circuit device having the connecting structure and an electronic apparatus having the circuit device.

### BACKGROUND ART

There has been known a circuit device in which a plurality of circuit boards are disposed in a stacked manner along the thickness direction of the board and the respective circuit boards are electrically connected via a connecting member disposed between the circuit boards (see Patent Literatures 1 and 2).

For example, a circuit device 100 of Patent Literature 1 as shown in FIG. 8 includes a first circuit board 111 and a second circuit board 121 disposed along the thickness direction of base members 110, 120, and a connection member 130 disposed between the first circuit board 111 and the second circuit board 121, wherein the first circuit board 111 and the second circuit board 121 are electrically connected by a terminal portion 131 provided at the connection member 130. In the circuit device 100 thus configured, a first circuit pattern 112 of the first circuit board 111 is connected to the terminal portion 131 of the connection member 130 and a second circuit pattern 122 of the second circuit board 121 is connected to the terminal portion 131 of the connection member 130.

Further, a circuit device 200 of Patent Literature 2 as shown in FIG. 9 is provided with a frame-shaped housing 210 having an inner peripheral portion 210A and an outer peripheral portion 210B, a plurality of connection terminal electrodes 220, 230 for connecting between the upper and lower surfaces of the housing 210, and bumps 240 provided on the plurality of connection terminal electrodes 220, 230 on at least one surface of the housing 210.

### CITATION LIST

### Patent Literature

Patent Literature 1: WO 2008/035442
Patent Literature 2: JP-A-2008-159983

In recent years, the performance of electronic devices has been improved, and there has been increased a need for increasing the mounting density of components by further effectively utilizing the limited surface of a board. Thus, a circuit device such as a standoff card connector is proposed which is configured to laminate a plurality of boards three-dimensionally via a pillar-shaped member (hereinafter called “a connection member”). Further, in such circuit device, with respect to a structure, that is, the connection member, for electrically connecting a first member (a circuit board) to a second member (a connector board), it is also required to develop the connection structure for wiring two kinds of terminals (hereinafter called “different kinds of terminals”) separately.

However, in the case of forming the connection member for the different kinds of terminals, securing of electric insulation becomes a very important problem in order to avoid the contact between these different kinds of terminals. Thus, in the case of realizing the connection structure with a simple configuration, it is considered to form the connection member by insulative resin etc. and to form the different kinds of terminals by being subjected to the metal plating etc. in a disposing state where the different kinds of terminals are mutually separated so as to secure the electric insulation therebetween.

In the case of forming the different kinds of terminals in the mutually separated state, the resin material of the connection member is exposed between the different kinds of terminals. In such a state, problems such as a crack or an exfoliation of the terminal likely occur inevitably at the external edge portion (a boundary portion between the connection member anti the terminal) of the exposed coupling member.

In particular, in the structure of stacking a plurality of components such as semiconductor packages or module boards in plural stages to thereby increase the height thereof (so-called a three-dimensional mounting structure), due to the influence of the weight and height of the components, a larger impact is likely applied to the components disposed at the lower position or to a part of the connecting portion located at the lower position.

With respect to such an impact, the component or the connecting portion is broken according to the structure thereof. For example, in the case of a rectangular structure, a crack occurs firstly at the corner portion thereof where a largest stress is applied. In the case of the structure of stacking components along the height direction thereof, the exfoliation between the components starts to occur from the connecting portion.

The circuit device of Patent Literature 1 is configured as shown in FIG. 10, for example, in a manner that a terminal portion 131 of a rectangular shape in section is provided at the periphery of a beam member 140 as the connection member 130. That is, the terminal portion 131 of the connection member 130 has a simple connection structure where only one kind of the terminal is formed. Thus, the connection structure is not configured in a manner that the different kinds of terminals such as a plurality of grounding terminals and signal terminals are formed to suppress a crack and an exfoliation of the terminal.

On the other hand, the circuit device described in Patent Literature 2 has the structure which is configured to surely connect between a plurality of circuit boards each having a mechanical deformation such as a warp with a thin structure and to have the electromagnetic shielding function. However, just as the circuit device described in Patent Literature 1, the circuit device described in Patent Literature 2 is also not configured in a manner that different kinds of terminals are formed to suppress a crack and an exfoliation of the terminal.

In view of the aforesaid circumstances, an object of the invention is to provide a connecting structure which can suppress the generation of problems such as a crack and an exfoliation of the terminal, and also to provide a circuit device having the connecting structure and an electronic apparatus having the circuit device.

### SUMMARY OF THE INVENTION

### Solution to Problem

A connecting structure according to the invention corresponds to a connecting structure for electrically and mechanically connecting between a first member and a second member, the connecting structure including a rectangular frame formed by insulative resin which at least includes a first connection surface to be connected to the first member, a second connection surface to be connected to the second member, and a first side surface and a second side surface each crossing with the first connection surface and the second connection surface; a connection terminal which includes a conductive first terminal portion formed at the first connection surface and a conductive second terminal portion formed at the second connection surface; a conductor which is formed at the first side surface to electrically connect the first terminal portion and the second terminal portion; and a concave portion which is formed on the first connection surface, wherein the first terminal portion is formed along the concave portion and has an end portion within the concave portion, and the insulative material of the frame is exposed between the end portion of the first terminal portion and the second side surface.

In this way, since the first terminal portion is formed along the concave portion, that is, formed so as to enter into the connection surface, the adhesion intensity between the first terminal portion and the frame can be enhanced and problems such as the generation of a crack and an exfoliation of the first terminal portion from the frame can be suppressed.

Further, since the insulative material of the frame exposes between the end portion of the first terminal portion provided at the concave portion and the second side surface, the first terminal portion does not reach the second side surface. That is, the end portion of the first terminal portion does not expose on the second side surface. Accordingly, since the first terminal portion thus enhanced in its adhesion density does not expose on the second side surface, the problems such as the generation of a crack and an exfoliation of the first terminal portion from the frame can be further suppressed.

Further, a connecting structure as one aspect of the invention corresponds to a connecting structure for electrically and mechanically connecting between a first member and a second member, the connecting structure including a rectangular frame formed by insulative resin that includes a first connection surface to be connected to the first member, a second connection surface to be connected to the second member, and a first side surface and a second side surface each crossing with the first connection surface and the second connection surface; a connection terminal which includes a conductive first terminal portion formed at the first connection surface and a conductive second terminal portion formed at the second connection surface; a conductor which is formed at the first side surface and the second side surface to electrically connect the first terminal portion and the second terminal portion in a loop manner; and a concave portion which is formed at the first connection surface, wherein the first terminal portion is formed along the concave portion and has a flat portion between the concave portion and the first side surface and also has a flat portion between the concave portion and the second side surface.

Further, as one aspect of the invention, the connecting structure is configured in a manner that one of the connection terminals is a signal terminal for electrically connecting the first member and the second member and the other of the connection terminals is a grounding terminal connected to the ground.

According to the aforesaid configuration, since the adhesion intensity between the frame and the signal terminal or the grounding terminal can be increased, the problems such as the generation of a crack and an exfoliation of the signal terminal ore the grounding terminal from the frame can be suppressed.

Further, as one aspect of the invention, the connecting structure is configured in a manner that the connection terminals are aligned in the longitudinal direction of the frame and disposed in a line symmetrical manner with respect to a center line of the external shape of the frame.

Accordingly, in the case of connecting the terminals by using the solder, the terminals are joined at the positions in the line symmetrical manner with respect to the component due to the self-alignment effects of the component caused by the surface tension at the time of melting the solder. Thus, since the mounting intensity of the component also becomes in the line symmetrical manner, the connection stability can be secured.

Further, as one aspect of the invention, the connecting structure is configured in a manner that a conductor of a loop shape is formed on the second side surface of the frame along the rectangular shape of the frame.

Accordingly, when the conductor of the loop shape along the rectangular shape of the frame is connected to the grounding terminal provided at the frame, since the conductor has the shield function, noise such as electromagnetic waves generated inside and outside of the connecting structure can be shielded.

Further, the circuit device according to the invention includes the aforesaid connecting structure, a first board having a land portion joined to the first terminal portion and a second board having a land portion joined to the second terminal portion.

Accordingly, the circuit device having a large joining intensity between the first board and the second board can be provided.

Further, as one aspect of the invention, the circuit device is configured in a manner that solder for connecting the first terminal portion or the second terminal portion with the land portion is completely filled within the concave portion.

Accordingly, an impact stress applied to the solder connection portion is dispersed into the frame via the concave portion, whereby the generation of a crack can be suppressed.

Further, as one aspect of the invention, the circuit device is configured in a manner that the first terminal portion or the second terminal portion has a flat portion between the first side surface and the concave portion, and the solder for connecting the first terminal portion or the second terminal portion with the land portion is filled between the first terminal portion or the second terminal portion and the land portion and also filled only at a part of the concave portion in the area between the flat portion to the bottom portion of the concave portion.

Accordingly, an impact stress applied to the solder connection portion is dispersed into the frame via the concave portion, whereby the generation of a crack can be suppressed. Further, since the end portion of the terminal portion is not soldered, the generation of an exfoliation of the end portion of the terminal portion at the connection surface can be suppressed.

Further, as one aspect of the invention, the circuit device is configured in a manner that the first terminal portion or the second terminal portion has a flat portion between the first side surface and the concave portion, and the solder for connecting the first terminal portion or the second terminal portion with the land portion is filled between the first terminal portion or the second terminal portion and the land portion but not filled in the concave portion.

Accordingly, since an impact stress applied to the solder connection portion is not applied to the concave portion, the generation of a crack can be suppressed. Further, since the end portion of the terminal portion is not soldered, the generation of an exfoliation of the end portion of the terminal portion at the connection surface can be suppressed.

Further, as one aspect of the invention, the circuit device is configured in a manner that an electronic component is mounted on the surface of at least one of the first board and the second board.

Accordingly, the circuit device having a large joining intensity between the first board and the second board can be provided.

Further, as one aspect of the invention, the circuit device is configured in a manner that the concave portion is formed at each of the first connection surface and the second connection surface and the first terminal portion and the second terminal portion are respectively formed along the concave portions.

Accordingly, since the circuit device having a large joining intensity between the first board and the second board is provided in the electronic apparatus such as a mobile terminal to which a large stress is applied instantaneously due to a shock caused by a falling thereof etc., the electronic apparatus can be provided which is excellent in the durability with respect to a shock caused by a falling thereof etc.

### ADVANTAGEOUS EFFECTS OF THE INVENTION

In the connecting structure according to the invention, the concave portion is formed at least one of the first connection surface and the second connection surface of the frame, and the first terminal portion or the second terminal portion of the connection terminal corresponding to the concave portion is formed along the concave portion and does not expose the end portion thereof on the side surface of the frame. Thus, the connecting structure according to the invention has a merit that the first terminal portion or the second terminal portion of the connection terminal enters into the concave portion of the frame to thereby enhance the adhesion intensity between the connection terminal and the frame, and further problems such as the generation of a crack and an exfoliation of the connection terminal portion from the frame can be suppressed.

### BRIEF DESCRIPTION OF THE DRAWINGS

FIG. 1 is a schematic perspective view showing the main portion of a mobile phone which is a kind of an electronic apparatus having a circuit device to which a connecting structure according to a first embodiment of the invention is applied.

FIG. 2 is a sectional view along a line II-II in FIG. 1.

FIG. 3 is a plan view of a relay connector.

FIG. 4 is sectional views showing the relay connector of the circuit device shown in FIG. 1, in which (A) is a sectional view along a line IVA-IVA shown in FIG. 3, and (B) is a sectional view along a line IVB-IVB shown in FIG. 3.

In FIG. 5, (A) and (B) are sectional views showing single-line area and plural-lines area of the relay connector of a circuit device according to a second embodiment, respectively.

In FIG. 6, (A) and (B) are sectional views showing single-line area and plural-lines area of the relay connector of a circuit device according to a third embodiment, respectively.

In FIG. 7, CA) and (B) are sectional views showing single-line area and plural-lines area of the relay connector of a circuit device according to a fourth embodiment, respectively.

FIG. 8 is an exploded perspective view showing a circuit device of a related art.

FIG. 9 is a plan view showing another circuit device of a related art.

FIG. 10 is a sectional view showing a connection member of the circuit device in FIG. 8.

### DESCRIPTION OF THE EMBODIMENTS

Hereinafter, an embodiment of the invention will be explained in detail with reference to accompanying drawings.

### First Embodiment

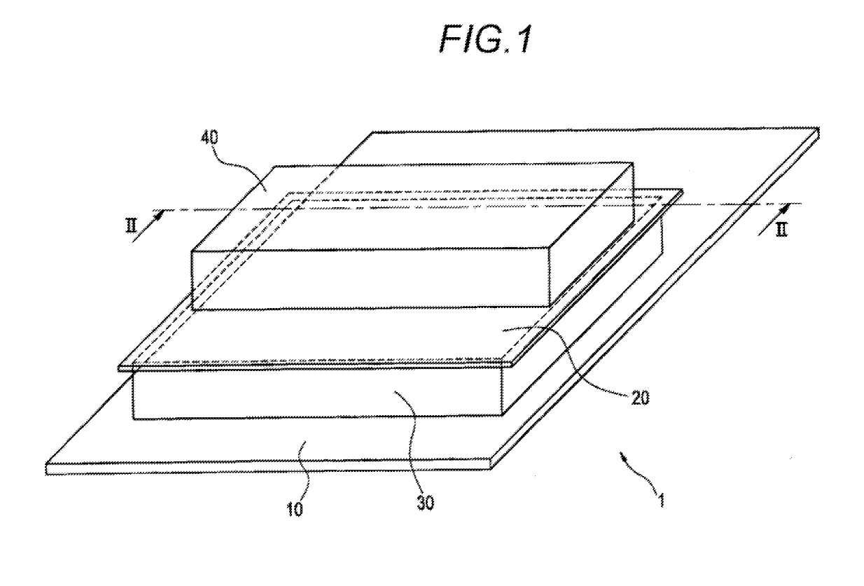

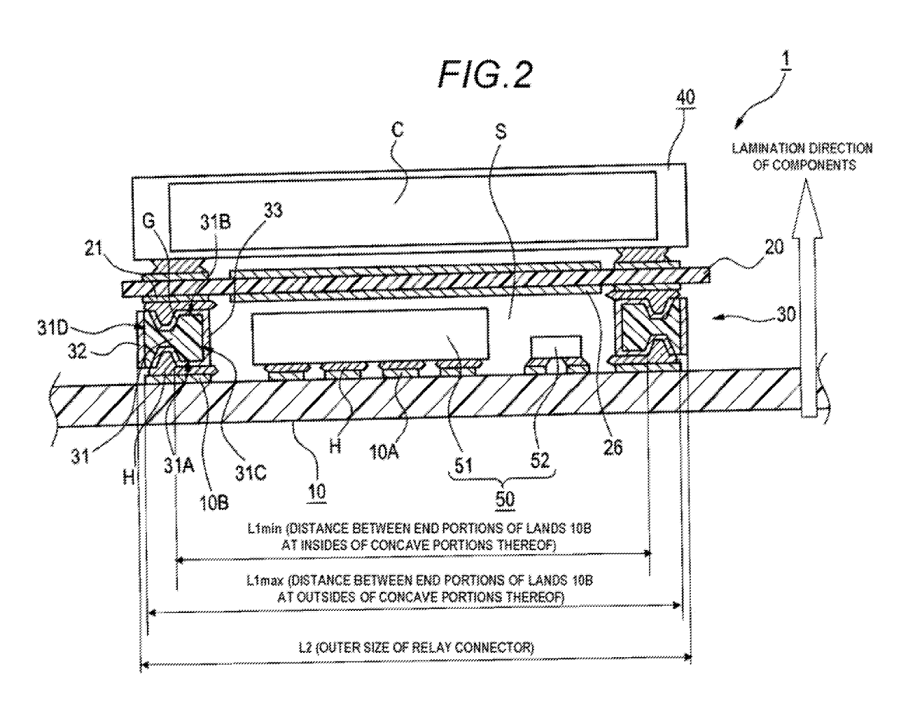

FIGS. 1 and 2 show the main portion of a circuit device 1 to which a connecting structure according to a first embodiment of the invention is applied. The connecting structure and the circuit device according to the invention can be used for an electronic apparatus such as a mobile phone, preferably. The circuit device 1 according to the embodiment includes, as a general configuration, a connector board 20 constituting a first member (first board), a circuit board 10 constituting a second member (second board), a relay connector portion 30 constituting the connecting structure (in other words, constituting a standoff portion) according to the invention, a card connector portion 40, and electronic components 50 mounted in a mounting space S provided between the circuit board 10 and the connector board 20.

In this embodiment, the circuit board 10 supports the card connector portion 10 on one surface thereof (an upper surface in FIG. 1: hereinafter called “a surface”) via the relay connector portion 30 and the connector board 20. The electronic components 50 are mounted on the surface of the circuit board 10 via board electrodes 10A and solders H, and also not-shown electronic components and a key sheet or a liquid crystal display apparatus (LCD) etc. are mounted on the opposite surface thereof. (a lower surface in FIG. 1). Further, as shown in FIG. 2, wiring patterns and the board electrodes 10A are formed by the etching processing or the plating processing of conductor on the surface of the circuit board 10. In particular, an electrode land for connecting the relay connector portion 30 is called as a land portion 10B.

The connector board 20 includes a first surface (hereinafter called “an upper surface”) opposing to the card connector portion 40 and a second surface (hereinafter called “a lower surface”) opposing to the surface of the circuit board 10, and wiring patterns 26 are formed on the upper and lower surfaces thereof. In particular, an electrode land for connecting the relay connector portion 30 is called as a land portion 21.

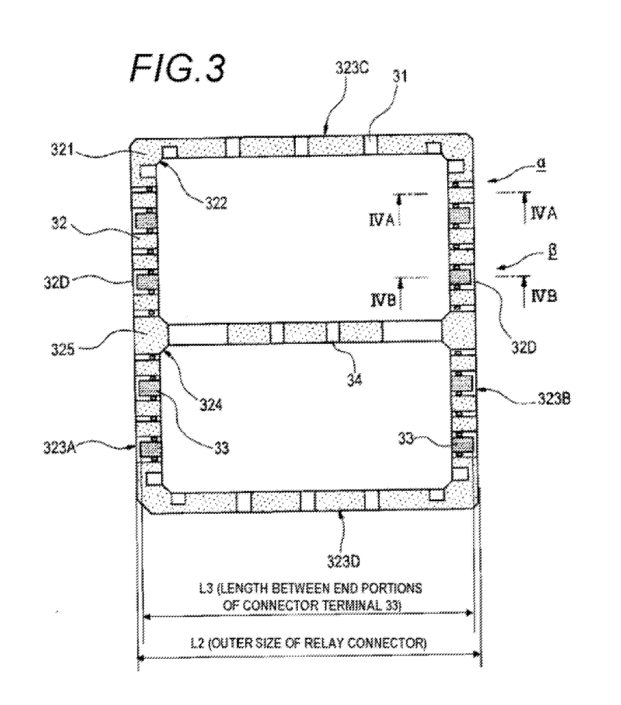

As shown in FIG. 3, the relay connector portion 30 is configured in a manner that the casing portion thereof is formed by a frame 31 and a beam portion 34 and that conductor portions (electrodes) are formed by the plating processing, and the relay connector portion further includes a first connection terminal 32 constituting a grounding terminal and second connection terminal 33 constituting a signal terminal. The grounding terminal is a terminal which is electrically connected to the ground (i.e., grounded), and the signal terminal is a terminal which electrically connects the connector board 20 with the circuit board 10 and relays a signal between the connector board 20 and the circuit board 10.

The relay connector portion 30 is formed by using suitable insulative resin (injection molding material such as LCP, PEEK, PEI, PES, PSF, SPS, PA, PPO or PPE or sintering material such as ceramics). As shown in FIG. 3, the frame 31 is formed by four outer sides 323A to 323D. Further, as shown in FIGS. 2 and 5, the frame 31 includes a first connection surface (upper surface) 31A to be connected to the connector board 20, a second connection surface (lower surface) 31B to be connected to the circuit board 10, and a first side surface 31C and a second side surface 31D each crossing with the first connection surface 31A and the second connection surface 31B.

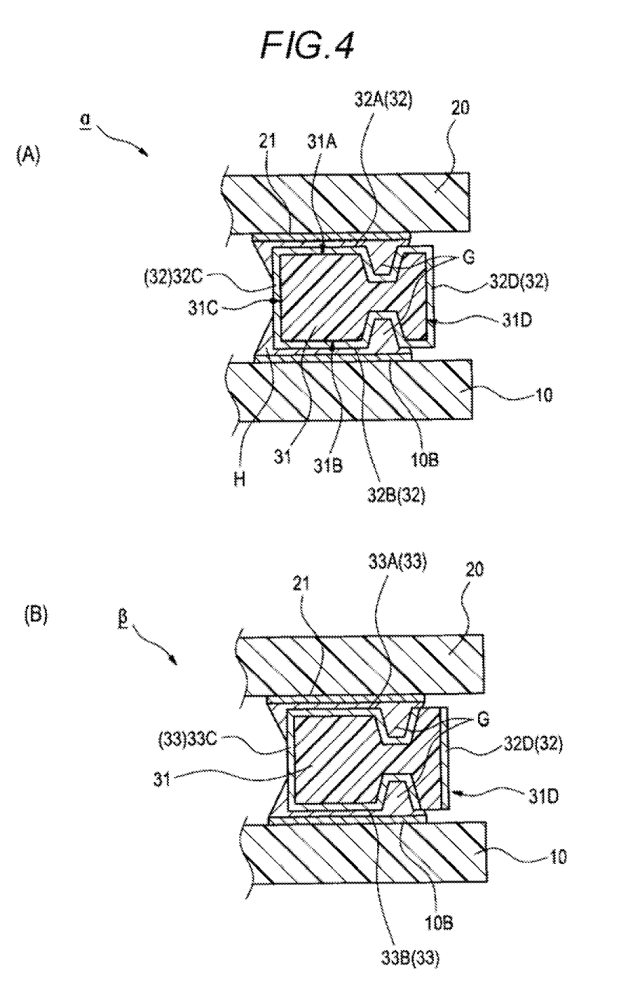

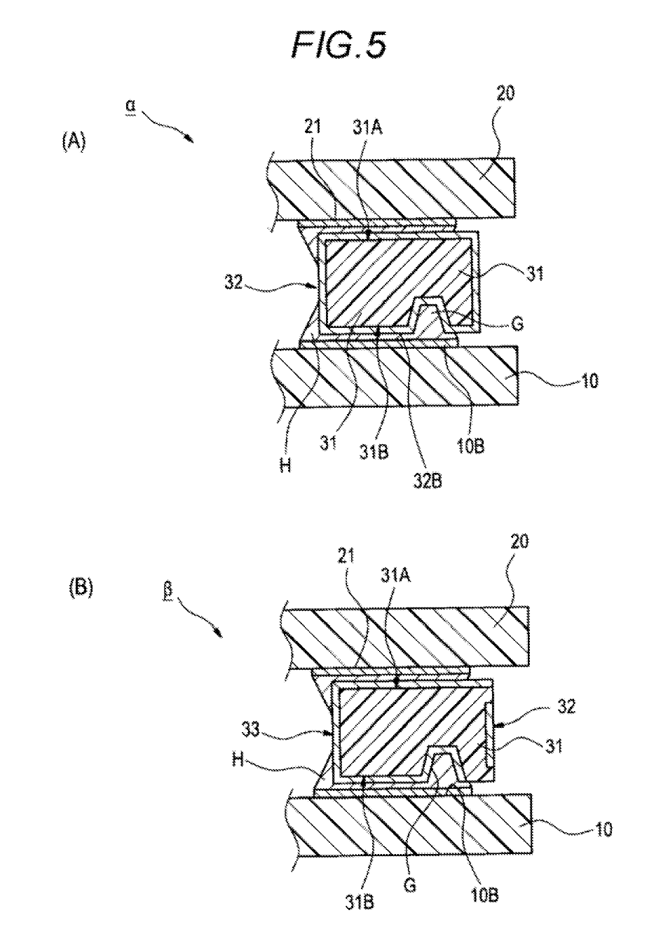

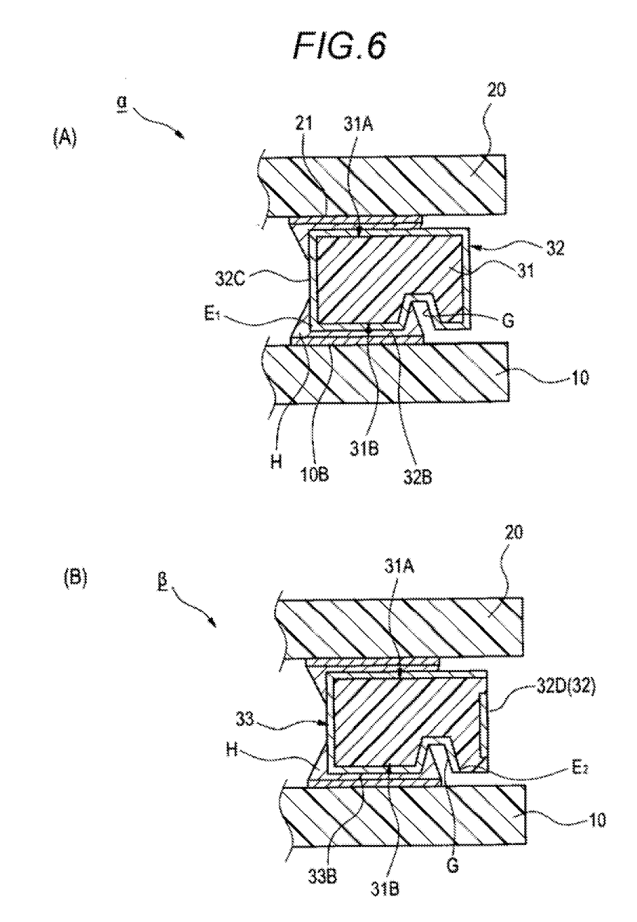

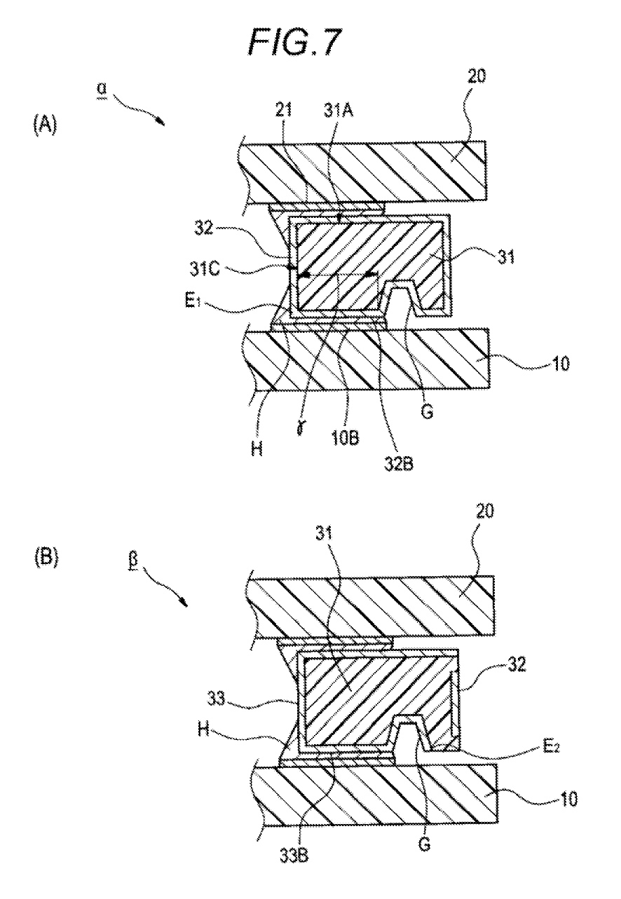

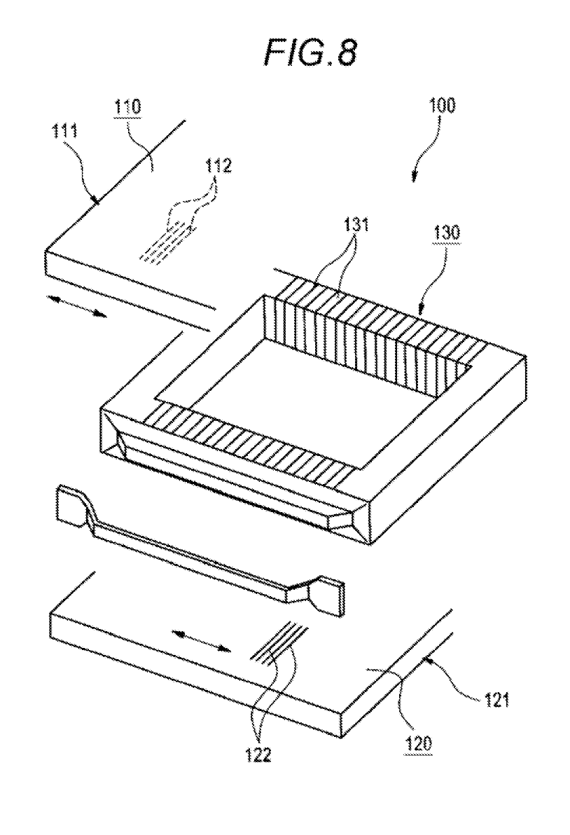

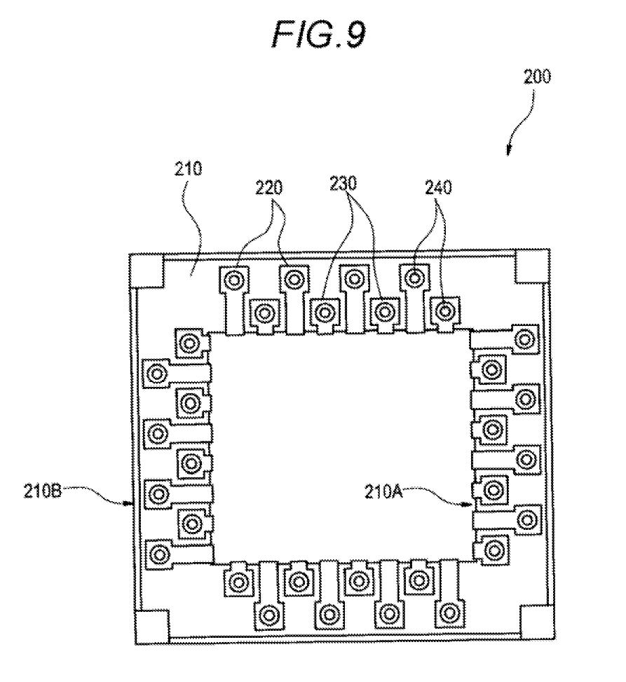

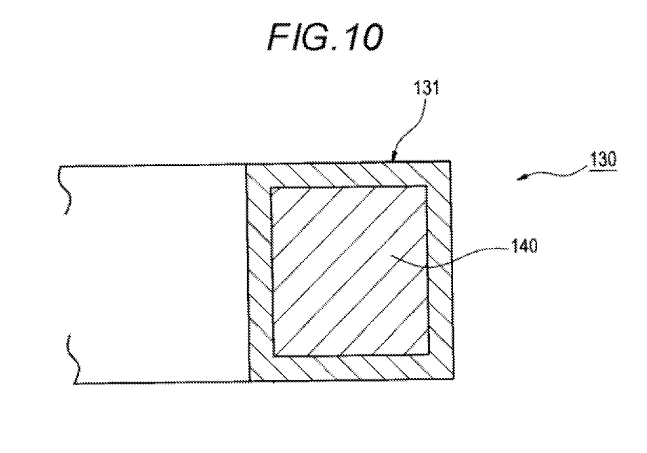

The frame 31 has a portion (hereinafter called “a single-line area α”) where only the first connection terminal 32 is disposed in a loop manner as shown in (A) of FIG. 4, and has a portion (hereinafter called “a plural-lines area β”) where different kinds of terminals of the first connection terminal 32 and the second connection terminal 33 are disposed together as shown in (B) of FIG. 4.

In other words, in the single-line area of the frame 31 shown by a sectional view along a line IVA-IVA in FIG. 3, the first connection terminal 32 is disposed in an almost rectangular shape in its cross-section over all the four surfaces constituting the outer peripheral surface thereof. On the other hand, in the plural-lines area of the frame 31 shown by a sectional view along a line IVB-IVB in FIG. 3, the first connection terminal (grounding terminal) 32 is disposed only on the second side surface 31D and the second connection terminal (signal terminal) 33 is disposed in an almost U shape (a shape rotating a character U by 90 degrees) in its cross-section on the three side surfaces of the outer peripheral surface including the first connection surface 31A, the second connection surface 31B and the first side surface 31C. In the latter plural-lines area, the first connection terminal 32 and the second connection terminal 33 are disposed separately. In other words, the frame 31 formed by insulative resin is exposed between the connection terminals 32 and 33 to thereby secure the insulation property therebetween.

Further, as shown in FIGS. 2 and 4, the frame 31 according to the invention is provided with a concave portion G at each of the first connection surface 31A and the second connection surface 31B. That is, at the concave portion G in the single-line area α of the frame 31, the first terminal portion 32A and the second terminal portion 32B of the first connection terminal 32 are formed along the concave portion G as shown in (A) of FIG. 4. Further, at the concave portion G in the plural-lines area β of the frame 31, the first terminal portion 33A and the second terminal portion 33B of the second connection terminal 33 are formed along the concave portion G as shown in (B) of FIG. 4.

The first connection terminal (hereinafter called “the grounding terminal”) 32 is formed by the plating processing (electroless plating processing or electrolytic plating processing) on the outer surface of the frame 31 formed by the insulative material. As described above, in the single-line area α shown in (A) of FIG. 4, the grounding terminal 32 according to the embodiment is formed in a state of electrically connecting the first terminal portion 32A provided on the first connection surface 31A to be connected to the connector board 20, the second terminal portion 32B provided on the second connection surface 31B to be connected to the circuit board 10, and a coupling portion 32C and a conductor 32D respectively provided on the first side surface 31C and the second side surface 31D each crossing with the first connection surface 31A and the second connection surface 31B, whereby a loop shape is formed in the cross-section of the frame 31.

When the grounding terminal 32 is formed in the loop shape, the grounding terminal surrounds the frame (in the section thereof) integrally over the four side surfaces thereof (that is, the first connection surface 31A, the second connection surface 31B, the first side surface 31C and the second side surface 31D). Thus, since there is no portion forming a notch of the conductor causing the exfoliation of the grounding terminal 32, the generation of the exfoliation can be effectively suppressed.

Further, according to the invention, the first terminal portion 32A and the second terminal portion 32B are formed on the first connection surface 31A and the second connection surface 31B in the state of being entered into the concave portions G formed at the parts of the first connection surface 31A and the second connection surface 31B, respectively. In this manner, since the first terminal portion 32A and the second terminal portion 32B can be formed in the state of being entered into the concave portions G of the frame 31, the adhesion intensity between the frame 31 and the first connection terminal 32, the second terminal portion 32B can be enhanced. As a result, the exfoliation of the grounding terminal 32 and the second terminal portion 32B from the frame 31 can be suppressed effectively.

Further, according to the embodiment, not only the first terminal portion 32A and the second terminal portion 32B but also the solder H for connecting the first terminal portion 32A (or the second terminal portion 32B) with the land portion 21 (or the land portion 10B) formed by the plating processing is placed in a state of being completely filled into the concave portion G. In this manner, in particular, when the solder is completely filled into the concave portion G, the frame 31 can be firmly coupled to the connector board 20 and the circuit board 10.

Further, due to the presence of the concave portion G, since the contact area between the grounding terminal 32 and the frame 31 increases, a stress acting therebetween is likely dispersed within the frame 31, so that the generation of a crack and an exfoliation of the grounding terminal 32 occurs unlikely.

Further, with respect to the grounding terminal 32, in the plural-lines area β where the signal terminals (signal lines) 33 are required to be disposed simultaneously as shown in (B) of FIG. 5, the conductor 32D is formed only at the one surface (second side surface 31D) of the frame 31 except for the three surfaces where the signal terminals 33 are disposed. However, the conductor 32D is connected to the terminal portions etc. of the grounding terminal 32 formed over all the four surfaces of the frame 31 in the single-line area α shown in (A) of FIG. 4 (this single-line area occupies most part of the outer side portion of the frame 31 as shown in FIG. 3). Thus, since the intensity of the grounding terminal 32 is further secured, the generation of a crack and an exfoliation of the terminal can be prevented more effectively.

In this manner, as to the grounding terminal 32 according to the invention, the grounding terminal 32 is provided on all the surfaces (four surfaces) of the frame 31 in the single-line area where the signal terminal (signal line) 33 is not disposed. That is, as shown in (B) of FIG. 4, the frame 31 is integrated over all the surfaces (four surfaces) so as to surround the frame 31 (in its section) in a loop manner. As a result, since there is no portion forming a notch which causes the notch and the exfoliation of the grounding terminal 32, the generation of a crack and an exfoliation of the terminal can be suppressed effectively

Further, a plurality of the grounding terminals 32 are formed in the longitudinal direction of the frame 31. In particular, in this embodiment, many grounding terminals are formed along the outer side direction so as to occupy the frame 31 with a large ratio. At least two the grounding terminals 32 are electrically and physically connected so as to be made conductive therebetween via the conductor 32D on one of the first side surface 31C and the second side surface 31D of the frame 31. In this embodiment, the two grounding terminals 32 are integrated via the conductor 32D at the second side surface 31D (external side portion) as shown in FIG. 3 and (B) of FIG. 4, for example. Thus, since these grounding terminals act mutually to suppress the generation of a crack or an exfoliation of the terminal, the generation of a crack or an exfoliation of the terminal can be further suppressed.

Further, as shown in FIG. 2, the land portion 10B of the same shape as the land portion 10B provided on the circuit board 10 is also provided at a position opposing thereto in a line symmetrical manner with respect to the center line of a connector component. Thus, in the case of performing the soldering connection, the land portions are fixed at the positions in the line symmetrical manner with respect to the center line of the connector component due to the self-alignment effects caused by the surface tension at the time of melting the solder Thus, since a stress applied to the terminal is dispersed symmetrically within the component when seen from the center line thereof, the generation of a crack or an exfoliation of the terminal can be mutually suppressed and hence the generation of a crack or an exfoliation of the terminal can be further suppressed.

Further, as shown in FIG. 3, the grounding terminal 32 according to the embodiment is provided with a first chamfer portion 322 of a plane shape at a corner portion 321 where the two outer sides (for example, the outer side 323A in the longitudinal direction and the outer side 323C in the transversal direction) among the four outer sides constituting the frame 31 crosses to each other. That is, since the grounding terminal 32 integrally surrounds the frame 31 also at the corner portion 321 of the frame 31, there is no portion forming a notch of the conductor which causes the exfoliation from the frame 31, the generation of an exfoliation can be suppressed.

Further, when the frame 31 is seen as a whole, the grounding terminal 32 is formed over all the four outer sides 322A to 322D of the frame 31. That is, the grounding terminal 32 is configured in a manner that all the four outer side portions are continued integrally. Thus, the generation of an exfoliation is further suppressed mutually while mutually reinforcing, whereby the generation of a crack and an exfoliation of the terminal can be further effectively suppressed.

Further, as shown in FIG. 3, in the two outer sides 323A and 323B of the frame 31 extending in the vertical direction, a second chamfer portion 324 of a plane shape is formed at the coupling portion with a beam portion 34 for coupling between the outer sides 323A and 323B. The second chamfer portion 324 is also provided with the grounding terminal 32 over an area thereof from the outer sides 323A, 3238 to the beam portion 34. That is, since the second chamfer portion 324 is also surrounded by the grounding terminal 32 in a loop manner, there is no portion forming a notch of the conductor which causes an exfoliation, so that the generation of a crack and an exfoliation of the terminal can also be suppressed at the second chamfer portion 324.

On the other hand, like the grounding terminal 32, the second connection terminal 33 (hereinafter called “a signal terminal”) is formed on the external surface of the frame 31 formed by the insulative material by the plating processing. In particular, as shown in FIG. 3, the signal terminal 33 according to the invention is formed between the two adjacent grounding terminals 32 in the longitudinal direction of the frame 31 (direction along four the outer sides 323A to 323D in FIG. 4).

As shown in (B) of FIG. 4, the signal terminal 33 is formed on the three surfaces, that is, the first connection surface (lower surface) 31A, the second connection surface (upper surface) 31B and one of the first side surface 31C and the second side surface 31D to which the grounding terminal 32 is not connected (the three surfaces except for the second side surface 31D in this embodiment). Thus, the signal terminal 33 is separated from the grounding terminal 32. That is, since the insulative frame 31 is exposed between the grounding terminal 32 and the signal terminal 33, the grounding terminal 32 is insulted from the signal terminal 33.

As shown in FIGS. 2 and 3, the signal terminal 33 of the same shape as the signal terminal 33 is also formed at a position opposing thereto in a line symmetrical manner with respect to the center line of the connector component. In this case, in FIG. 2, the distance (length) L3 between the end portions of the concave portions of the signal terminals coincides with the maximum length L1max of the distance (length) L1 between the end portions of the land portions 10B. In the case where the land portion is larger than this size, when the signal terminal 33 is connected to the land portion 10B by the soldering, there may arise a case that the solder spreads over the land portion to thereby short-circuit between the signal terminal and the grounding terminal 32.

On the other hand, supposing that the outer size in the short side direction of the relay connector is L2, the separation distance (length) between the grounding terminal 32 and the signal terminal 33 is (L2−L3)/2. Since this separation distance is provided within the connection surface, the end portion of the signal terminal portion does not expose on the side surface of the frame, whereby the structure unlikely occurring the exfoliation between the layers of the terminal is realized.

Like the grounding terminal 32, the signal terminal 33 includes the first terminal portion 33A provided on the first connection surface (upper surface) 31A to be connected to the connector board 20, the second terminal portion 33B provided on the second connection surface (lower surface) 31B to be connected to the circuit board 10, and a coupling portion 33C provided on the first side surface 31C crossing with the first connection surface 31A and the second connection surface 31B.

Further, like the aforesaid grounding terminal 32, the signal terminal 33 is configured in a manner that the first terminal portion 33A and the second terminal portion 33B are formed on the first connection surface 31A and the second connection surface 31B in a state of entering into the concave portions G formed at parts of the first connection surface 31A and the second connection surface 31B of the frame 31, respectively. That is, also in the signal terminal 33, each of the first terminal portion 33A and the second terminal portion 33B enters into the concave portion G of the frame 31. Thus, the exfoliation of the first terminal portion 33A and the second terminal portion 33B of the signal terminal 33 from the frame 31 can be suppressed effectively.

Further, also in the signal terminal 33 according to the embodiment, the solder H for connecting the first terminal portion 33A and the second terminal portion 33B with the land portions 21, 10B formed by the plating processing of the connector board 20 and the circuit board 10 is completely filled into the concave portions G, respectively. Thus, like the signal terminal 33, in particular, when the concave portion G is completely filled by the solder, the frame 31 can be connected firmly with the connector board 20 and the circuit board 10.

With respect to the concave portion G according to the invention, although the explanation is made as to the configuration where single concave portion is provided for each connection terminal, a plurality of concave portions may be provided for each connection terminal.

Further, with respect to the concave portion G according to the invention, although the explanation is made as to the configuration where the concave portions of the same size and the same shape are disposed on the same vertical line (on a line in the same vertical direction) on each of the first connection surface and the second connection surface, the concave portions may not have the same size and the same shape and not be disposed on the same vertical line.

The beam portion 34 is formed by using suitable insulative material and provided so as to connect between the opposing two frames 31. The frame 31 and the beam portion 34 are connected via a branch portion 325. The aforesaid second chamfer portion 324 is formed at the brunch portion 325.

The electronic component 50 is mounted by using the mounting space S which is the space area between the card connector portion 40 and the connector board 20 on the surface of the circuit board 10. As the electronic components 50, surface mounting devices (SMD) such as a semiconductor package component 51 and an LCR circuit chip component 52 are used. The electronic components are mounted on the surface of the circuit board 10. The electronic components 50 may be attached on the connector board 20 side instead of the circuit board 10 side so long as they are disposed in the mounting space S formed between the circuit board 10 and the connector board 20.

Thus, according to this embodiment, the grounding terminals 32 and the signal terminals 33 can be formed on the same area (plural-lines area) of the frame 31 separately in an insulated state therebetween while suppressing the generation of a crack and an exfoliation of the terminal.

Further, according to the embodiment, as described above, the concave portions G are formed in the frame 31 and the terminals are formed in a state of entering into the concave portions G. Thus, the firm connection between the circuit board and the frame 31 is realized. Further, when the connecting structure according to the embodiment is applied, the circuit device having a large joining intensity can be realized with respect to the connector board 20 as the first board and the circuit board 10 as the second board.

Further, according to the embodiment, even in the case of joining the board having a large weight in which the electronic components 50 are mounted on the both surfaces of the connector board 20 and (or) the both surfaces of the circuit board 10, the circuit board can be realized which is large in the joining intensity and unlikely raises a crack and an exfoliation of the terminal.

Further, according to the embodiment, in the electronic apparatus such as a mobile terminal to which a large stress is applied instantaneously due to a shock caused by a falling thereof etc., since the circuit device having a large joining intensity between the connector board 20 and the circuit board 10 is provided, the electronic apparatus can be realized which is durable with respect to a shock caused by a falling thereof etc.

Although not shown in the drawings, when the insulative resin is provided at the outer periphery of the frame and the mounting area within the frame to thereby reinforce the frame, it will be clear that the electronic apparatus can be realized which has a further improved joining intensity and is further durable with respect to a shock caused by a falling thereof etc.

### Second Embodiment

Next, the explanation will be made with reference to FIG. 5 as to an electronic apparatus having a circuit device to which a connecting structure according to a second embodiment of the invention is applied. In this embodiment, portions identical to those of the first embodiment are referred to by the common symbols, with explanation thereof being omitted.

The circuit device of this embodiment differs from the circuit device of the first embodiment in a point that the frame 31 is configured to form the concave portion G only at the second connection surface (lower surface) 31B as shown in FIG. 5.

That is, in the structure of stacking a plurality of components such as semiconductor packages or module boards in plural stages to thereby increase the height thereof (so-called a three-dimensional mounting structure), due to the influence of the weight and height of the components, a larger impact is likely applied to the components disposed at the lower position or to a part of the coupling portion located at the lower position. In view of this matter, the concave portion G is formed only at the second connection surface (lower surface) 31B.

Thus, in the single-line area α of the frame 31 shown in (A) of FIG. 5, the second terminal portion 32B of the grounding terminal 32 is formed in a state of entering into the concave portion G of the second connection surface (lower surface) 31B. As a result, the exfoliation of the second terminal portion 32B from the frame 31 can be effectively suppressed. Further, the solder H for connecting the second terminal portion 32B with the land portion 10B formed by the plating processing of the circuit board 10 is completely filled into the concave portions G. Thus, since the solder is completely filled within the concave portion G, the frame 31 can be firmly connected to the circuit board 10.

On the other hand, in the plural-lines area β of the frame 31 shown in (B) of FIG. 5, the second terminal portion 33B of the signal terminal 33 is formed in a state of entering into the concave portion G of the second connection surface (lower surface) 31B. As a result, the exfoliation of the second terminal portion 33B from the frame 31 can be effectively suppressed. Further, also in this plural-lines area β, the solder H for connecting the second terminal portion 33B with the land portion 10B formed by the plating processing of the circuit board 10 is completely filled into the concave portions G. Thus, since the solder is completely filled within the concave portion G, the frame 31 can be firmly connected to the circuit board 10.

The configuration of the concave portion G according to the invention is not limited to that shown in this embodiment. The concave portion G may be disposed on the side applied with a larger impact stress in view of the magnitude of the impact stress applied to the connection portion within the circuit device or the electronic apparatus. That is, although the concave portion G is formed at the second connection surface 31B in this embodiment, the concave portion may be formed at the first connection surface 31A.

In this manner, when the connecting structure according to the embodiment, is applied, the circuit device having a large joining intensity can be realized with respect to the connector board 20 as the first board and the circuit board 10 as the second board.

Although not shown in the drawings, when the insulative resin is provided at the outer periphery of the frame and the mounting area within the frame to thereby reinforce the frame, it will be clear that the electronic apparatus can be realized which has a further improved joining intensity and is further durable with respect to a shock caused by a falling thereof etc.

### Third Embodiment

Next, the explanation will be made with reference to FIG. 6 as to a circuit device to which a connecting structure according to a third embodiment of the invention is applied. In this embodiment, portions identical to those of the second embodiment are referred to by the common symbols, with explanation thereof being omitted.

The circuit device of this embodiment is same as the circuit device of the second embodiment in a point that the concave portion G is formed only at the second connection surface (lower surface) 31B in the frame 31 and the second terminal portion 32B or 33B is formed at the entirety of the concave portion G but differs from the circuit device of the second embodiment only in a point that the solder H is filled only at a part of the concave portion G.

That is, in the single-line area α of the frame 31 shown in (A) of FIG. 6, the solder H for connecting the land portion 10B of the circuit board 10 with the second terminal portion 32B of the grounding terminal 32 is formed in an area from the left end portion E₁ of the first terminal portion 32A closer to the coupling portion 32C to an intermediate position not reaching the bottom portion of the concave portion G. That is, the solder H is filled only at a part within the concave portion G.

On the other hand, also in the plural-lines area β of the frame 31 shown in (B) of FIG. 6, the solder H for connecting the land portion 10B of the circuit board 10 with the second terminal portion 33B of the signal terminal 33 is filled only at a part within the concave portion G.

According to this embodiment, at the time of joining the land portion 10B with the second terminal portion 33B of the signal terminal 33 by the solder H, the solder H does not cover the other end portion E₂ of the second terminal portion 33B facing on the exposed portion of the frame 31. Thus, by using the adhesion intensity between the second terminal portion 33B and the frame 31 which is improved by the fact that only the second terminal portion 33B (not accompanying with the solder H) enters into the concave portion G of the frame 31, the generation of a crack and an exfoliation of the terminal at the end portion of the second terminal portion 33B can be further effectively suppressed.

The configuration of the concave portion G according to the invention is not limited to that of this embodiment. The concave portion G may be disposed, within the circuit device or the electronic apparatus, on a side applied with a larger impact stress in view of the magnitude of the impact stress applied to the coupling portion. That is, although the concave portion G is formed at the second connection surface 31B in this embodiment, the concave portion may be formed at the first connection surface 31A.

Thus, according to the embodiment, in the plural-lines area 6, the solder H does not cover the end portion of the second terminal portion 33B where the frame 31 exposes. Thus, the generation of an exfoliation at the second terminal portion 33B can be suppressed.

Although not shown in the drawings, when the insulative resin is provided at the outer periphery of the frame and the mounting area within the frame to thereby reinforce the frame, it will be clear that the electronic apparatus can be realized which has a further improved joining intensity and is further durable with respect to a shock caused by a falling thereof etc. In this case, this embodiment is configured to reinforce the concave portion G by the solder and the resin.

### Fourth Embodiment

Next, the explanation will be made with reference to FIG. 7 as to a circuit device to which a connecting structure according to a fourth embodiment of the invention is applied. In this embodiment, portions identical to those of the third embodiment are referred to by the common symbols, with explanation thereof being omitted.

The circuit device of this embodiment differs from the circuit device of the third embodiment in a point that the solder H provided for connecting between the second terminal portions 32B, 33B and the first land portion 10B of the circuit board 10 is not filled in the concave portions G of the second terminal portions 32B, 33B.

As shown in (A) of FIG. 7, the second terminal portion 32B of the grounding terminal 32 is configured to form a flat portion γ at an area from one end portion E₁ contacting to the first side surface 31C of the frame 31 to the concave portion G. On the other hand, the land portion 10B is disposed only at an area corresponding to the flat portion γ avoiding the concave portion G. That is, the land portion of this embodiment can be formed so as to have a narrow shape as compared with the land portions 10B in the first to third embodiments. Also in the plural-lines area 8 shown in (B) of FIG. 7, the second terminal portion 33B of the signal terminal 33 and the land portion 10B are configured in the similar manner.

In FIG. 2, the distance coincides with the minimum length L1min of the distance (length) L1 between the end portions of the land portions 10B. In the case where the land portion is smaller than this size, since the connection area for connecting between the signal terminal 33 and the land portion 10B by the solder reduces, there arises a fear that the joining intensity reduces.

Further, the land portion 10B is formed so as to have a narrow shape in correspondence to the flat portion γ of the second terminal portion 33B of the signal terminal 33. Thus, at the time of joining the land portion 10B with the second terminal portion 33B of the signal terminal 33, the solder H does not cover the other end portion E₂ of the second terminal portion 33B facing on the exposed portion of the frame 31. Therefore, by using the adhesion intensity between the second terminal portion 33B and the frame 31 which is improved by the fact that only the second terminal portion 33B (not accompanying with the solder H) enters into the concave portion G of the frame 31, the generation of a crack and an exfoliation of the terminal at the end portion of the second terminal portion 33B can be further effectively suppressed.

Although not shown in the drawings, when the insulative resin is provided at the outer periphery of the frame and the mounting area within the frame to thereby reinforce the frame, it will be clear that the electronic apparatus can be realized which has a further improved joining intensity and is further durable with respect to a shock caused by a falling thereof etc. In this case, this embodiment is configured to reinforce the concave portion G by the resin.

In the embodiments, the conductors are formed on the second side surfaces of all the four outer sides so that all the first connection terminals locate on the external sides of the four outer sides of the frame to thereby electrically connect the first connection terminals. According to this configuration, since all the first connection terminals are combined, it is possible to improve the intensity. However, all the first connection terminals are not necessarily connected via the conductors but a plurality of the first connection terminals may be connected via the conductors.

Further, the invention can be applied to a case where the frame, the connector board and the circuit board are joined by using isotropic conductive resin or anisotropic conductive resin other than the solder.

The invention is not limited to the aforesaid embodiment, and the changes and applications performed by persons skilled in the art based on the description of the specification and well-known techniques are estimated and contained within the range of the protection of the invention.

The present application is based on Japanese Patent Application No. 2009-068021 filed on Mar. 19, 2009, the contents of which is incorporated herein by reference.

### INDUSTRIAL APPLICABILITY

The invention has an effect that generation of a crack and an exfoliation of the terminal can be suppressed effectively with respect to two kinds of terminals having different functions which are provided on the same frame in a separated and insulated state to each other. The invention is useful for the circuit device provided with the connecting structure and the electronic apparatus having the circuit device.

### REFERENCE SIGNS LIST

1 circuit device
10 first member (circuit board)
10A board electrode
10B land portion
20 second member (connector board)
21 land portion
26 wiring pattern
30 relay connector portion (connecting structure)
31 frame
31A first connection surface (lower surface)
31B second connection surface (upper surface)
31C first side surface
31D second side surface
32 first connection terminal (grounding terminal)
32A first terminal portion
32B second terminal portion
32C coupling portion
32D conductor
323A-323D outer side
33 second connection terminal (signal terminal)
33A first terminal portion
33B second terminal portion
33C coupling portion
34 beam portion
40 card connector portion
50 electronic component
51 semiconductor package component
52 LCR circuit chip component
C card
E₂ the other end portion
G concave portion
H solder
S mounting space
α single-line area
β plural-lines area
γ flat portion

1.-13. (canceled)

14. A circuit device, comprising:
a first board which includes a first land portion;
a second board which includes a second land portion; and
a connecting structure which includes:
a rectangular frame formed by insulative material which at least includes a first connection surface connected to the first member, a second connection surface connected to the second member, and a first side surface and a second side surface each crossing with the first connection surface and the second connection surface;
a concave portion which is formed on the first connection surface;
a first terminal portion which is formed at the first connection surface along the concave portion, and is connected to the first land portion;
a second terminal portion which is formed at the second connection surface along the concave portion, and is connected to the second land portion; and
a conductor which is formed at the first side surface to electrically connecting the first terminal portion and the second terminal portion, wherein
the first terminal portion includes a flat portion between the first side surface and the concave portion, and
a solder for connecting the first terminal portion with the first land portion is filled between the first terminal portion and the first land portion and is also filled only at a part of inside of the concave portion.

15. The circuit device according to claim 14, wherein
the first terminal portion has an end portion within the concave portion, and
the insulative material of the frame is exposed between the end portion of the first terminal portion and the second side surface.

16. The circuit device according to claim 14, wherein
the conductor is formed at the first side surface and the second side surface, and electrically connects the first terminal portion and the second terminal portion in a loop manner.

17. The circuit device according to claim 14, wherein
each of the first terminal portion, the second terminal portion and the conductor is a signal terminal.

18. The circuit device according to claim 14, wherein
each of the first terminal portion, the second terminal portion and the conductor is a grounding terminal

19. The circuit device according to claim 14, wherein
the first terminal portion, the second terminal portion, and the conductor are aligned in the longitudinal direction of the frame and disposed in a line symmetrical manner with respect to a center line of the external shape of the frame.

20. The circuit device according to claim 14, wherein
a conductor of a loop shape is formed on the second side surface of the frame along the rectangular shape of the frame.

21. The circuit device according to claim 14, wherein
an electronic component is mounted on a surface of at least one of the first board and the second board.

22. The circuit device according to claim 14, wherein
the concave portion is formed at each of the first connection surface and the second connection surface, and the first terminal portion and the second terminal portion are respectively formed along the concave portions.

23. An electronic apparatus, comprising the circuit device according to claim 14.

24. A circuit device, comprising:
a first board which includes a first land portion;
a second board which includes a second land portion; and
a connecting structure which includes:
a rectangular frame formed by insulative material which at least includes a first connection surface connected to the first member, a second connection surface connected to the second member, and a first side surface and a second side surface each crossing with the first connection surface and the second connection surface;
a concave portion which is formed on the first connection surface;
a first terminal portion which is formed at the first connection surface along the concave portion, and is connected to the first land portion;
a second terminal portion which is formed at the second connection surface along the concave portion, and is connected to the second land portion; and
a conductor which is formed at the first side surface to electrically connecting the first terminal portion and the second terminal portion, wherein
the first terminal portion includes a flat portion between the first side surface and the concave portion, and
a solder for connecting the first terminal portion with the first land portion is filled between the flat portion and the first land portion and is not filled within the concave portion.

25. The circuit device according to claim 24, wherein
the first terminal portion has an end portion within the concave portion, and
the insulative material of the frame is exposed between the end portion of the first terminal portion and the second side surface.

26. The circuit device according to claim 24, wherein
the conductor is formed at the first side surface and the second side surface, and electrically connects the first terminal portion and the second terminal portion in a loop manner.

27. The circuit device according to claim 24, wherein
each of the first terminal portion, the second terminal portion and the conductor is a signal terminal.

28. The circuit device according to claim 24, wherein
each of the first terminal portion, the second terminal portion and the conductor is a grounding terminal

29. The circuit device according to claim 24, wherein
the first terminal portion, the second terminal portion, and the conductor are aligned in the longitudinal direction of the frame and disposed in a line symmetrical manner with respect to a center line of the external shape of the frame.

30. The circuit device according to claim 24, wherein
a conductor of a loop shape is formed on the second side surface of the frame along the rectangular shape of the frame.

31. The circuit device according to claim 24, wherein
an electronic component is mounted on a surface of at least one of the first board and the second board.

32. The circuit device according to claim 24, wherein
the concave portion is formed at each of the first connection surface and the second connection surface, and the first terminal portion and the second terminal portion are respectively formed along the concave portions.

33. An electronic apparatus, comprising the circuit device according to claim 24.
